(19) United States
(12) Patent Application Publication
(10) Pub. No.: US 2007/0103151 A1
(43) Pub. Date: May 10, 2007

(54) Inspection method and device for semiconductor equipment

(75) Inventor: Kiyoshi Nikawa, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kanagawa (JP)

(21) Appl. No.: 11/591,541

(22) Filed: Nov. 2, 2006

(30) Foreign Application Priority Data
Nov. 7, 2005 (JP) 2005-322166

(51) Int. Cl. G01R 33/02

(52) U.S. Cl. 324/248

(57) ABSTRACT

To improve spatial resolution of scanning microscopes including: a detector 130 that irradiates laser light modulated in its intensity with a modulation signal synchronized with a reference signal on an IC chip 110, receives magnetic field signals from a fluxmeter 120 and extracts signals with the same frequency components as the modulation frequency; a display 140 that displays images of the magnetic field distribution using the signal detected as described above; and the frequency of said modulation signal is higher than 100 kHz.

### FIELD OF THE INVENTION

The present invention relates to non-destructive inspection devices and such inspection methods, and more specifically to devices and methods suitable for locating a defective portion of semiconductor devices using a microscope with a magnetic field detector.

### BACKGROUND OF THE INVENTION

As a non-destructive inspection method for a sample like semiconductor wafers, an inspection method that employs a scanning laser SQUID (superconducting quantum interference device) microscope is known. When the laser beam is irradiated onto a defective portion or a portion related to the defect, an electric current flows. The laser-SQUID microscope detects the magnetic field induced by the current with a SQUID fluxmeter and obtains images by scanning the laser or samples as disclosed by Nikawa and Inoue, LSITS2000, pp. 203-208 (2000) [Non-patent Document 1]. When the laser beam is irradiated onto a substrate of a semiconductor sample, an electron-hole pair generated by the laser irradiation causes a current to flow by electric field at p-n junctions and so on. The current is called an OBIC (optical beam induced current) current. Since defects within the sample cause an imbalance in temperature gradients by irradiation heat of the laser beam, a current is caused to flow also by the thermoelectric effect [Refer to Non-patent Document 1, Patent Document 1 etc.].

Moreover, a detection method that extracts a signal with the same frequency as the modulation frequency from the detected magnetic field signals is employed in the scanning laser-SQUID microscopy to realize a practical S/N (signal to noise) ratio. Non-patent Document 1 discloses a criterion for selecting a modulation frequency having less environmental noise. To be more specific, a frequency of 8.3 kHz is selected. Non-Patent Document 2 also discloses a development of system with 100 kHz at the maximum to reduce time to obtain images by the scanning laser-SQUID microscopy, which improves the conventional system with 10 kHz at the maximum.

[Patent Document 1]

Japanese Patent Kokai Publication No. JP-P2002-313859A

[Non-Patent Document 1]

K. Nikawa and S. Inoue, “Novel non-destructive and non-contact failure analysis and process monitoring technique—Scanning laser-SQUID microscopy-”, LSITS2000, pp. 203-208, 2000

[Non-Patent Document 2]

K. Nikawa and H. Nakayama, “Scanning laser-SQUID microscope showing sub-micron spatial resolution observed from back-side of a wafer”, LSITS2002, pp. 275-280, 2002

[Non-Patent Document 3]

T. Sakai and K. Nikawa, “Observation of completed LSI after building-in defect using laser-SQUID microscopy”, LSITS2004, pp. 341-345, 2004

### SUMMARY OF THE DISCLOSURE

Positions such as p-n junction where photocurrent is induced by laser irradiation are located by scanning laser-SQUID microscope. There is a problem with such convectional inspection methods that images of the positions (such as p-n junction where photocurrents are induced by the laser irradiation) obtained by the methods are blurred (i.e., out of focus) except certain special cases and poor in spatial resolution than those by optical microscopes.

Therefore, the localizing (or focusing) accuracy of the defective position by the conventional inspection methods has been about 100 micrometers at most as disclosed in the Non-patent Document 3, for example.

It is an object of the present invention to provide a completely novel method to overcome the above-mentioned problem. According to the present invention, there is provided a novel inspection method characterized by increasing the modulation frequency higher than those in the conventional methods.

For example, images of a higher resolution are obtained by the scanning laser-SQUID microscope based on modulation frequencies higher than 100 kHz which has been conventionally 100 kHz at the maximum.

According to a first aspect of the present invention, there is provided an inspection method comprising: generating laser light modulated in its intensity with a modulation signal (i.e., synchronized with a reference signal) and scanning a sample with the modulated laser light; detecting magnetic field induced from the sample using a magnetic field detector; extracting a magnetic field signal of the same frequency component as the modulation frequency from magnetic field signals detected by the magnetic field detector; outputting the extracted signal as an image display signal; wherein the modulation frequency is higher than 100 kHz.

An inspection device according to the present invention is characterized by comprising: a detector that extracts a magnetic field signal from the sample of the same frequency component as the modulation frequency higher than 100 kHz during the irradiation of the modulated laser light on the sample; and a display that displays images using the signal extracted by the detector as an image display signal.

According to a second aspect of the present invention, there is provided a detector that irradiates laser light modulated with a modulation frequency higher than 100 kHz on a sample, receives magnetic field signals from a magnetic field detector that detects the magnetic field induced from the sample and extracts a signal of the same frequency component as the modulation frequency; and a display that displays images using the signal extracted by the detector as an image display signal.

The device according to the present invention comprises: a modulated beam generating unit that generates laser light modulated in its intensity with a modulation signal synchronized with a reference signal; an optical system that irradiates the modulated laser light on a sample; a magnetic field detector; a scanner that scans the modulated laser light relatively to the sample; a extractor that receives magnetic field signals from the magnetic field detector and extracts a signal of the same frequency component as the modulation frequency; and a display that generates and displays a magnetic field from the extracted signal; wherein the modulation frequency is higher than 100 kHz.

The meritorious effects of the present invention are summarized as follows.

The present invention makes it possible to obtain scan images with higher spatial resolution than those by conventional methods. As described in detail in the following, the reason is thought that the travel length through distribution of minor carriers during one period of the modulated frequency becomes shorter as the frequency becomes higher.

### BRIEF DESCRIPTION OF THE DRAWINGS

FIG. 1 shows an embodiment of the present invention.

FIG. 2A shows configuration of a device as an embodiment of the present invention, and FIG. 2B shows schematically timing waveforms of magnetic field signals, reference signals and modulation signals.

### PREFERRED EMBODIMENTS OF THE INVENTION

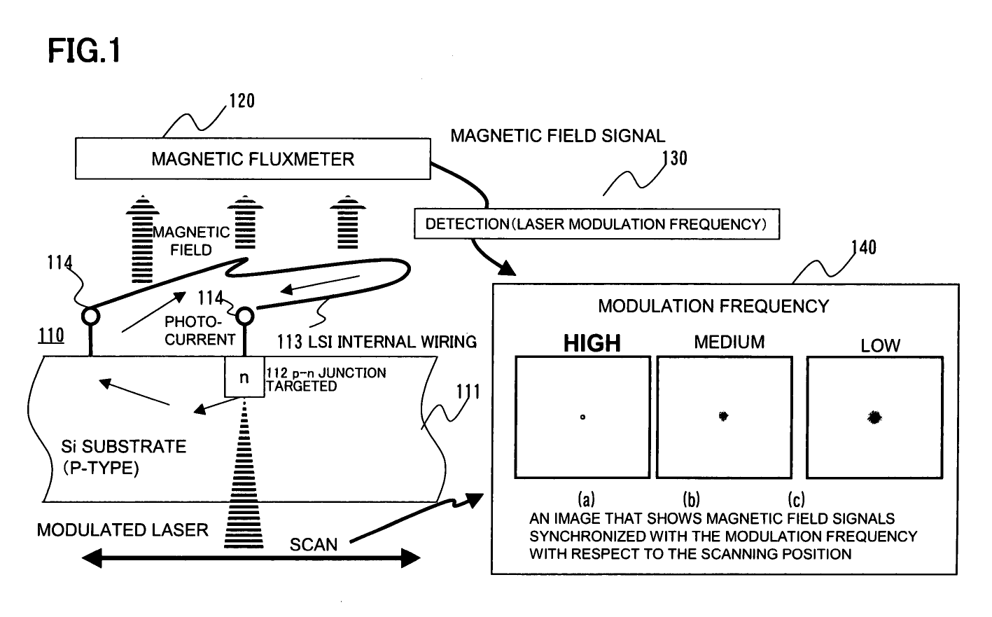

Embodiments of the present invention are described below in more detail referring to the attached drawings. In the present invention a sample for inspection is scanned by relative movement (or displacement) between the irradiation spot (position) of a laser beam and the sample, and the magnetic field is detected with a highly sensitive magnetic field sensor to obtain a magnetic field image. FIG. 1 shows an inspection method according to one embodiment of the present invention.

According to the present invention, as shown first in FIG. 1, when an OBIC current (photocurrent) is generated by irradiation of a laser beam modulated in their intensity with a predetermined frequency onto the back surface of an IC chip 110, a magnetic field is induced and the magnetic flux is detected with a magnetic fluxmeter (a highly sensitive magnetic field sensor) 120 that is arranged against the main side of the chip, to form a magnetic field detector. Two dimensional images that correspond to the magnetic field distribution can be obtained by scanning the laser beam over the back surface of the IC chip (or moving the sample relative to the fixed laser light) and displaying the intensity (distribution) of the magnetic flux detected by the magnetic fluxmeter 120 in association with the scanning position information of the IC chip 110 on a display device based on gradation display (brightness display), for example.

Moreover, output voltage that corresponds to strength of the magnetic field is output by the fluxmeter 120, and a signal that is output from the magnetic fluxmeter 120 and selected for having only the same frequency as the modulation frequency of the laser with the detector 130 is converted to gradation data of the pixel in association with positions irradiated with the laser beam in a signal processor (or a data processor), followed by displaying on a display device 140. In this way, image data of the magnetic field distribution (scanning image of the magnetic field distribution) are obtained. The purpose of irradiation of the laser beam onto the back surface of the IC chip is to make the laser beam reach p-n junction 112 near the surface of silicon substrate 111 of the IC chip 110. That is, when they are irradiated from the top side of the IC chip 110, the laser beams reflect on the metal wiring layer within the upper layers of silicon substrate of the IC chip and so on and does not reach the p-n junction 112 near the surface of the silicon substrate 111. Moreover, when wafers and chips are inspected, they are preferably finished up with mirror polishing.

FIG. 1 is a schematic illustration of scanned images of a p-n junction 112 near and in the surface of the silicon substrate 111 in association with the modulation frequency on a display device 140. Merely for explanation, FIG. 1 shows three display images (a), (b) and (c) that correspond to relatively high, medium and low modulation frequencies, respectively, as an example of the scanning microscope image displayed on the display device 140 for explanation. This does not necessarily mean that these three images are always displayed at the same time. On the contrary, each of these three images is displayed individually. FIG. 1 shows that spatial resolution becomes higher as the modulation frequency becomes higher. As a magnetic fluxmeter 120, a SQUID fluxmeter is preferably employed in the present embodiment. However, it is not limited to the SQUID fluxmeter. Any highly sensitive magnetic field sensor can be employed.

In the following, the reason why the spatial resolution becomes higher as the modulation frequency becomes higher is analyzed. For simplifying the explanation, FIG. 1 shows a case where images of one p-n junction 112 are obtained by a scanning laser microscope. The laser is modulated and scans the region that includes p-n junctions. When the laser hits the p-n junction 112, a photocurrent is generated and flows into an LSI internal wiring 113 through electrodes 114 connected with both ends of the p-n junction. A magnetic field induced by the current is detected with the magnetic fluxmeter 120 and used as a magnetic field signal and displayed on the display device 140.

As described above, not all the magnetic field signals are used to display images but only the components having the same frequency as the laser modulation frequency are extracted with the detector 130 and used as image display signals.

The photocurrent flows even if the laser beam doesn't just hit the p-n junction 112.The reason is explained by the phenomenon called carrier diffusion. The carrier diffusion occurs when carrier densities are not uniform. When electron-hole pairs are generated by the irradiation of the laser beam, the minority carrier meets this condition.

When the laser beam is irradiated onto a silicon substrate (Si), electron-hole pairs are generated. When there is a p-n junction at the irradiation position, the electron and the hole are pulled apart immediately by the internal electric field of a depletion layer existing there to form a current.

On the other hand, the generated minority carriers evenly spread out toward the surroundings by diffusion, when the irradiated position is not the p-n junction. Then, the minority carriers recombine to extinguish while spreading. When the minority carriers arrive at a p-n junction before extinction, they form a photocurrent by the internal electric field.

As understood by the foregoing explanation, the area (boundary) within which the carriers generated by the laser irradiation can reach within one period of the laser modulation frequency expands (i.e., is large) when the modulation frequency is low.

An image that extends to form a circle is obtained, for example, as shown in the display image (c) with a caption “low” within the display device 140 in FIG. 1.

When the frequency is raised beyond that, area of the extension decreases as shown in the image (b) with a caption “medium”.

When the frequency is raised still further, an image of almost only the p-n junction is obtained as shown in the image (a) with a caption “high”.

In this way, the spatial resolution is improved by raising the modulation frequency. The experiment on the display image and the consideration are the original findings of the present inventor.

That is, it has not been recognized conventionally that the size of the image would change with the frequency. Therefore, as stated above, the selection of the frequency has been done as follows. Namely, a frequency with less environmental noise has been chosen as a laser modulation frequency in Non-patent Document 1, for example, and a certain high frequency has been chosen in Non-patent Document 2 in order to decrease the time to obtain scanning laser SQUID microscope images.

The frequency with low environmental noise can be selected irrespective of the magnitude of the frequency. Moreover, it has been unnecessary to develop a system in which a frequency over 100 kHz can be selected, because the frequency of at most 100 kHz is enough to decrease the time to obtain the images.

According to the present invention, the spatial resolution of about 100 micrometers in the conventional methods are improved by one digit or more by raising the modulation frequency up to a level of higher than 100 kHz. Hereafter, the present invention is explained along with an embodiment.

[Embodiments]

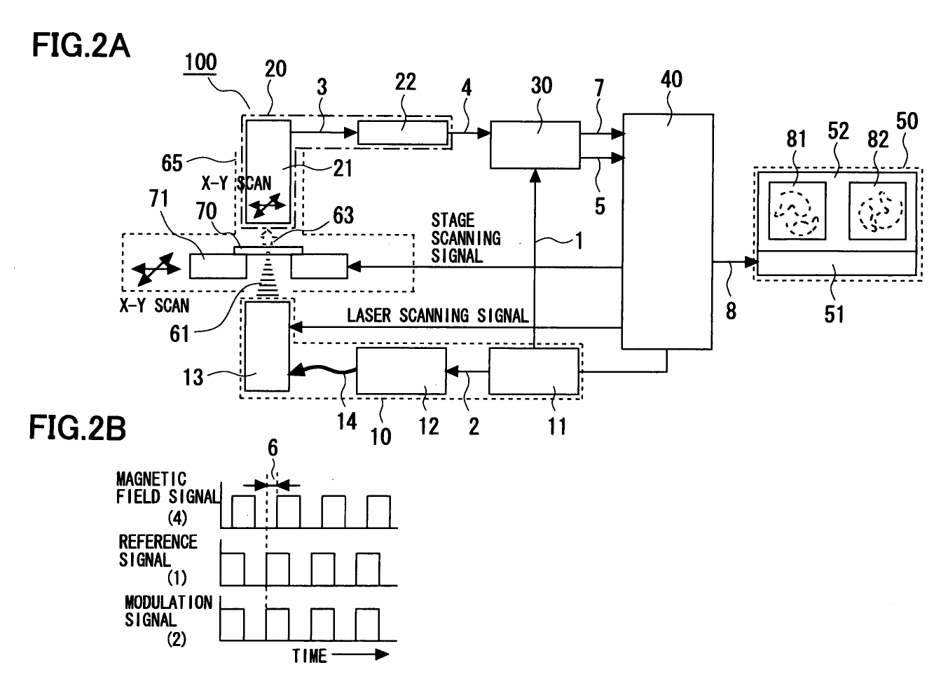

FIG. 2A shows one example of a device structure that embodies the present invention. FIG. 2B shows an example of a timing waveform of reference signal 1, modulation signal 2 and magnetic field signal 4 in FIG. 2A. According to FIG. 2A, this inspection device comprises: a modulated beam generating unit 10 that generates light modulated in its intensity by a signal 2 synchronized with a predetermined reference signal 1 and focuses to generate a modulated laser beam 61; a sample stage 71, on which a sample 70 is located, that moves so that a predetermined position of the sample is irradiated by the modulated beam 61; a magnetic detection unit 20 that detects a magnetic field (magnetic flux) induced by a current generated during the irradiation of the modulated beam 61 onto the sample 70 and outputs magnetic field signals 4; a signal extractor 30 that extracts the magnetic field intensity and the phase difference 6 (see FIG. 2B) between the reference signal 1 and the magnetic field signal 4 and outputs them as an intensity signal 5 and a phase difference signal 7, respectively; a system controller (abbreviated as controller) that controls irradiation of the modulated beam 61 onto the sample 70 and positioning of the sample stage 71 according to the information on the irradiation position, inputs the intensity signal 5 and the phase-difference signal 7 and outputs these signals in association with the information on the irradiation position; and a display 50 that receives at least one of the intensity signal 5 or the phase difference signal 7 and information on the irradiation position, and displays resultant images.

The modulated beam generating unit 10 comprises: a pulse generator 11 that generates and outputs the reference signal 1 and the modulation signal 2 (see FIG. 2B) synchronized with the reference signal 1; a fiber laser and the like with a modulation function specifically comprising; a laser light source 12 that generates light (laser light) modulated in its intensity with the modulation signal 2 output from the pulse generator 11; an optical fiber 14 that guides the laser light; and an optical unit 13 that focuses the light guided by the optical fiber 14 and generates a modulated beam 61.

The magnetic field detection unit 20 comprises a SQUID fluxmeter 21 that works as a highly sensitive magnetic field sensor and an electronic circuit (also called as a SQUID electronic circuit) 22 that controls the SQUID fluxmeter 21, generates a magnetic field signal 4 from the output signal 3 (output voltage) of the SQUID fluxmeter 21 and outputs these signals. For example, a high-temperature superconducting SQUID is employed as the SQUID fluxmeter 21. A flux-locked loop (FLL) circuit may be employed as the electronic circuit 22. The SQUID fluxmeter 21 should be so highly sensitive as to sense the magnetic flux changing with as specified high frequency in association with the modulated laser light of the specified high modulation frequency.

The signal extractor 30 comprises a two-phase lock-in amplifier (not shown in the drawings) for example although it is not restricted to such amplifier, receives the magnetic field signal 4 from the electronic circuit 22 and detect a signal with the same frequency as the modulation signal 2. Moreover, the signal extractor 30 may output the intensity of the extracted signal (with the same frequency as the modulation frequency) and the phase difference between the magnetic field signal 4 and the modulation signal 2 as output signals 5 and 7, respectively.

The controller 40 controls the position of the sample stage 71 (or the sample 70) according to stage scanning signals, for example, controls optical unit 13 of the modulated beam generating unit 10 in FIG. 1 if necessary and so on and irradiates the sample 70 while scanning the modulated beam 61 over the sample 70.

The control unit 40 uses signals, detected (extracted) by the signal extractor 30, that have the same frequency component(s) as the modulation frequency as the image display signal and supplies them to the display unit 50. The control unit 40 receives the intensity signal 5 and the phase difference signal 7 and controls the display of images with the scanning laser SQUID microscope synchronized with the stage scan, the laser light irradiation position or scanning of the SQUID fluxmeter, although it is not limited to this case. The control unit 40 outputs image display signal 8 as a combination of information on the irradiation position of the modulated beam 61 and the intensity signal 5 and phase difference signal 7 both of which are in association with the information on the irradiation position.

The display unit 50 comprises a PC (personal computer) 51 and a display 52, receives the image display signal 8 from the control unit 40, and output an intensity image 81 in association with the magnetic field at the laser-beam scanning position and a phase difference image 82 corresponding to the phase difference. Moreover, as shown in FIG. 2A, it is preferred to show both the intensity image 81 and the phase difference image 82 as the image of the magnetic field distribution, although only one image has been shown in the above explanation of FIG. 1 to make the explanation easier.

Next, an example of operations for the present embodiment shown in FIGS.2A and 2B is explained. In the present embodiment, IC chips or Si wafers are used as a sample 70. Needless to say, compound semiconductor wafers, TFT substrates and the like may be also used. The sample 70 is located on the sample stage 71, a reference signal 1 and a modulation signal 2 synchronized with the reference signal are generated by the pulse generator 11, the reference signal 1 is output to the signal extractor 30, the modulation signal 2 is output to the laser light source 12 composed of fiber laser (of 1,065 nm in wavelength, for example) equipped with a modulation function, intensity-modulated laser light is generated, guided to the optical system unit 13 through the optical fiber 14 and the modulated beam (laser beam) is focused on the sample 70.

When the modulated beam 61 is irradiated onto the first irradiation spot, the SQUID fluxmeter 21 detects a magnetic field from the sample 70 and the electronic circuit 22 outputs a magnetic field signal 4. The signal extractor 30 receives the magnetic field signal 4 and outputs the intensity signal of the magnetic field signal 4 having the same frequency as the modulation signal 2 and the phase difference signal 7 (of the magnetic field signal from the modulation or reference signal) to the control unit 40.

The control unit 40 outputs the intensity signal 5 and phase difference signal 7 corresponding to the irradiation position of the modulated beam 61 to the PC 51. The PC 51 memorizes the intensity signal 5 and the phase difference signal 7 in a storage unit (not shown in the drawings) of the PC 51.

The irradiation spots within the desired inspection area are selected sequentially by x-y scan of the sample stage 71 controlled by the stage scan signal combined with the scan of the modulated beam 61 controlled by the laser scan signal if necessary; the desired irradiation spots within the inspection region are sequentially selected and irradiated by the modulated beam 61; and the intensity signal 5 and the phase difference signal 7 are stored in the storage of PC 51 as the image display signal 8 in accordance with the information on the position of the irradiation spot.

The PC 51 displays images on the display 52 with a gradation (brightness) display in correspondence with the intensity signal 5 or phase difference signal 7 and the laser irradiation points of the sample 70 (Refer to FIG. 2A). In this case, either intensity image 81 corresponding to the intensity signal 5 or the phase difference image 82 corresponding to the phase difference signal 7 may be displayed. The magnetic field images may be displayed in real time in association with the scanning spot. Moreover, the image of the intensity signal 5 and phase difference signal 7 stored in the storage corresponding to the scanning position may be displayed offline on the display 52 when the entire scans over one sample is finished or at any time afterwards by memorizing the gradation (brightness) data of the intensity signal 5 and phase difference signal 7 corresponding to scanning positions. Of course, printers, file devices and the like may be used instead of the display.

In the present embodiment, employment of a fiber laser device equipped with modulation function as a laser generator 12 makes it possible that the frequency of the modulation signal 2 is set to any values up to, e.g., 1 M Hz at a maximum as far as the presently available facility is concerned. When the S/N (signal to noise) ratio is low because of weak magnetic field signals, the modulation frequency should be selected so as to reduce the noise. This does not necessitate changing the frequency in a large extent. Since the laser light of 1,065 nm in wavelength is employed in the present embodiment, the modulated laser beam irradiated onto the back surface of a Si wafer 70 penetrates the silicon substrate and reaches the p-n junction (region) near the Si wafer surface. Silicon wafers with a mirror-polished back surface are preferred, because the modulated beams 61 irradiated onto the back surface of Si wafers reach around p-n junction (region) efficiently.

When a HTS (high temperature superconducting) SQUID fluxmeter is used as a SQUID fluxmeter 21, it is possible to detect a magnetic flux density B of 1 pT or less. Moreover, the SQUID fluxmeter is equipped with a magnetic shield 65. It usually detects magnetic flux perpendicularly to the surface of the sample 70.

Since the output magnetic field signal 4 from the electronic circuit 22 usually includes noises, extraction of the same frequency component as the modulation frequency with a two-phase lock-in amplifier (signal extractor 30) improves the S/N ratio. The employment of a two-phase lock-in amplifier as the signal extractor 30 makes it possible not only to extract only the same frequency component(s) as the modulation frequency 2 but also to output the phase difference signal 7 and the intensity signal 5 as separate data. When the chip size is 6 mm by 10 mm for example, the image of the magnetic field distribution is captured by focusing the modulated beam 61 into a beam of 10 microns diameter and by scanning the sample stage 71 composed of a ceramic stage in x-y direction(s) (x- or y-direction, or x-y directions).

A modulation frequency higher than 100 kHz is chosen for example. Then an intensity image 81 and a phase difference image 82 are obtained.

Although the configuration shown in FIG. 2A has been explained based on an example where the intensity signal and the phase difference signal showing phase difference between the magnetic field signal and the reference signal are output individually from the magnetic field signal detected with a magnetic field detection unit, it is certainly applicable to the case where only the intensity signal is output. Moreover, although the explanation has been based on the example where a SQUID fluxmeter 21 is employed as a highly sensitive magnetic field sensor, the present invention is not limited to the case of scanning SQUID microscopy with a SQUID fluxmeter. The present invention is applicable to scanning microscopy with any highly sensitive magnetic field sensor.

Although it has been explained according to the above embodiment, the present invention is not limited to the construction of the above embodiment. It is, of course, that various modifications and variations by persons skilled in the art fall within the spirit and scope of the present invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. An inspection method, comprising:
generating laser light modulated in its intensity with a modulation signal and scanning a sample relatively with said modulated laser light;
detecting magnetic field induced from said sample with a magnetic field detector;
extracting a signal of the same frequency component as said modulation frequency from magnetic field signals detected by said magnetic field detector;
outputting the extracted signal as an image display signal; wherein said modulation signal has a frequency higher than 100 kHz.

2. The inspection method according to claim 1, wherein
said magnetic field detector includes a highly sensitive magnetic field sensor.

3. The inspection method according to claim 1, wherein said magnetic field detector includes a SQUID (superconducting quantum interference device) fluxmeter.

4. The inspection method according to claim 1, wherein said extracted signal further includes a phase difference signal of said magnetic field signal from said modulation signal.

5. An inspection device comprising:
a detector that irradiates laser light modulated with a modulation frequency higher than 100 kHz on a sample, receives magnetic field signals from a magnetic field detector that detects the magnetic field induced from said sample and extracts a signal of the same frequency component as said modulation frequency; and
a display that displays images using the signal extracted by said detector as an image display signal.

6. An inspection device comprising:
a modulated beam generator that generates laser light modulated in its intensity with a modulation signal;
an optical system that irradiates modulated laser beam onto a sample;
a magnetic field detector;
a scanner that scans said modulated laser light relatively to said sample;
a detector that receives magnetic signals from said magnetic field detector and extracts a signal of the same frequency component as that of said modulation signal; and
a display that displays images using the signal extracted by said detector as an image display signal; wherein said modulation signal has a frequency higher than 100 kHz.

7. The inspection device according to claim 5, wherein said magnetic field detector includes a highly sensitive magnetic field sensor.

8. The inspection device according to claim 6 wherein said magnetic field detector includes a highly sensitive magnetic field sensor.

9. The inspection device according to claim 5, wherein said magnetic field detector includes a SQUID fluxmeter.

10. The inspection device according to claim 6, wherein said magnetic field detector includes a SQUID fluxmeter.

11. The inspection device according to claim 5, wherein said detector further detects a phase difference signal of said magnetic field signal from said modulation signal.

12. The inspection device according to claim 6, wherein said detector further detects a phase difference signal of said magnetic field signal from said modulation signal.
